(19) United States
(12) Patent Application Publication
(10) Pub. No.: US 2023/0020503 A1
(43) Pub. Date: Jan. 19, 2023

(54) MACHINE CONTROL

(71) Applicant: Ford Global Technologies, LLC, Dearborn, MI (US)

(72) Inventors: Yousaf Rahman, Ypsilanti, MI (US); Subramanya Nageshrao, San Jose, CA (US); Michael Hafner, San Carlos, CA (US); Hongtei Eric Tseng, Canton, MI (US); Mrdjan J. Jankovic, Birmingham, MI (US); Dimitar Petrov Filev, Novi, MI (US)

(73) Assignee: Ford Global Technologies, LLC, Dearborn, MI (US)

(21) Appl. No.: 17/370,411

(22) Filed: Jul. 8, 2021

(51) Int. Cl. G05D 1/02; G06N 3/08; G06K 9/62

(52) U.S. Cl. CPC G05D 1/0221; G06N 3/08; G06K 9/6277

(57) ABSTRACT

A computer, including a processor and a memory, the memory including instructions to be executed by the processor to determine a first action based on inputting sensor data to a deep reinforcement learning neural network and transform the first action to one or more first commands. One or more second commands can be determined by inputting the one or more first commands to control barrier functions and transforming the one or more second commands to a second action. A reward function can be determined by comparing the second action to the first action. The one or more second commands can be output.

### BACKGROUND

Machine learning can perform a variety of computing tasks. For example, machine learning software can be trained to determine paths for operating systems including vehicles, robots, product manufacturing and product tracking. Data can be acquired by sensors and processed using machine learning software to transform the data into formats that can be then further processed by computing devices included in the system. For example, machine learning software can input sensor data and determine a path which can be output to a computer to operate the system.

### BRIEF DESCRIPTION OF THE DRAWINGS

FIG. 1 is a block diagram of an example system.

FIG. 2 is a diagram of an example traffic scene.

FIG. 3 is a diagram of another example traffic scene.

FIG. 4 is a diagram of a further example traffic scene.

FIG. 5 is a diagram of an example deep neural network

FIG. 6 is a diagram of an example vehicle path system.

FIG. 7 is a diagram of an example graph of deep neural network training.

FIG. 8 is a diagram of an example graph of control barrier functions.

FIG. 9 is a diagram of an example graph of acceleration corrections.

FIG. 10 is a diagram of an example graph of steering corrections.

FIG. 11 is a flowchart diagram of an example process to operate a vehicle using a deep neural network and control barrier functions.

### DETAILED DESCRIPTION

Data acquired by sensors included in systems can be processed by machine learning software included in a computing device to permit operation of the system. Vehicles, robots, manufacturing systems and package handling systems, can all acquire and process sensor data to permit operation of the system. For example, vehicles, robots, manufacturing system and package handling systems can acquire sensor data and input the image data to machine learning software to determine a path upon which to operate the system. For example, machine learning software in a vehicle can determine a vehicle path upon which to operate the vehicle that avoids contact with other vehicles. A machine learning software in a robot can determine a path along which to move an end effector such as a gripper on a robot arm to pick up an object. Machine learning software in a manufacturing system can direct the manufacturing system to assemble a component based on determining paths along which to move one or more sub-components. Machine learning software in a package handling system can determine a path along which to move an object to a location within the package handline system.

Vehicle guidance as described herein is a non-limiting example of using machine learning to operate a system. For example, machine learning software executing on a computer in a vehicle can be programmed to acquire sensor data regarding the external environment of the vehicle and determine a path along which to operate the vehicle. The vehicle can operate based on the vehicle path by determining commands to control one or more of the vehicle's powertrain, braking, and steering components, thereby causing the vehicle to travel along the path.

Deep reinforcement learning (DRL) is a machine learning technique that uses a deep neural network to approximate a Markov decision process (MDP). An MDP is a discrete-time stochastic control process that models system behavior using a plurality of states, actions, and rewards. An MDP includes one or more states that summarize the current values of variables included in the MDP. At any given time, an MDP is in one and only one state. Actions are inputs to a state that results in a transition to another state included in the MDP. Each transition from one state to another state (including the same state) is accompanied by an output reward function. A policy is a mapping from the state space (a collection of possible states) to the action space (a collection of possible actions), including reward functions. A DRL agent is a machine learning software program that can use deep reinforcement learning to determine actions that result in maximizing reward functions for a system that can be modeled as an MDP.

A DRL agent differs from other types of deep neural networks by not requiring paired input and output data (ground truth) for training. A DRL agent is trained using “trial and error”, where the behavior of the DRL agent is determined by exploring the state space to maximize the eventual future reward function at a given state. A DRL agent is a good technique for approximating an MDP where the states and actions are continuous or large in number, and thus difficult to capture in a model. The reward function encourages the DRL agent to output behavior selected by the DRL trainer. For example, a DRL agent learning to operate a vehicle autonomously can be rewarded for changing lanes to get past a slow-moving vehicle.

The performance of a DRL agent can depend upon the dataset of actions used to train the DRL agent. If the DRL agent encounters a traffic situation that was not included in the dataset of actions used to train the DRL agent, the output response of the DRL agent can be unpredictable. Given the extremely large state space of all possible situations that can be encountered by a vehicle operating autonomously in the real world, eliminating edge cases is very difficult. An edge case is a traffic situation that occurs so seldom that it would not likely be included in the dataset of actions used to train the DRL agent. A DRL agent is a non-linear system by design. Because it is a non-linear system, small changes in input to a DRL agent can result in large changes in output response. Because of edge cases and non-linear responses, the behavior of a DRL agent cannot be guaranteed, meaning that the behavior of a DRL agent to previously unseen input situations can be difficult to predict.

Techniques described herein improve the performance of a DRL agent by filtering the output of the DRL agent with control barrier functions (CBF). A CBF is a software program that can calculate a minimally invasive safe action that will prevent violation of a safety constraint when applied to the output of the DRL agent. For example, a DRL agent trained to operate a vehicle can output unpredictable results in response to an input that was not included in the dataset used to train the DRL agent. Operating the vehicle based on the unpredictable results can cause unsafe operation of the vehicle. A CBF applied to the output of a DRL agent can pass actions that are determined to be safe onto a computing device that can operate the vehicle. Actions that are determined to be unsafe can be overridden to prevent the vehicle from performing unsafe actions.

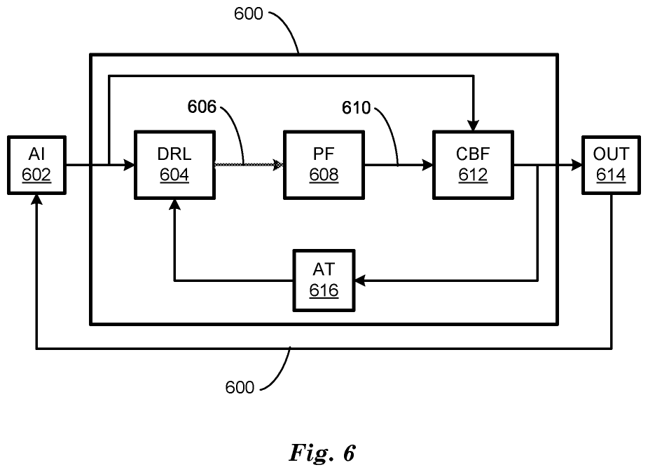

Techniques described herein combine a DRL agent with a CBF filter that permits a vehicle operate with a DRL agent trained with a first training dataset and then adapt to different operating environments without endangering the vehicle or other nearby vehicles. High-level decisions made by the DRL agent are translated into low-level commands by path follower software. The low-level commands can be executed by a computing device communicating commands to vehicle controllers. Prior to communication to the computing device, the low-level commands are input to a CBF along with positions and velocities of surrounding vehicles to determine whether the low-level commands can be safely executed by the computing device. Safely executed by the computing device means that the low-level commands, when communicated to vehicle controllers, would not cause the vehicle to violate any of the rules included in the CBF regarding distances between vehicles or limits on lateral and longitudinal accelerations. A vehicle path system that includes a DRL agent and a CBF is described in relation to FIG. 6, below.

A method is disclosed herein, including determining a first action based on inputting sensor data to a deep reinforcement learning neural network, transforming the first action to one or more first commands and determining one or more second commands by inputting the one or more first commands to control barrier functions. The one or more second commands can be transformed to a second action, a reward function can be determined by comparing the second action to the first action, and the one or more second commands can be output. A vehicle can be operated based on the one or more second commands. The vehicle can be operated by controlling vehicle powertrain, vehicle brakes, and vehicle steering. Training the deep reinforcement learning neural network can be based on the reward function. The first action can include one or more longitudinal actions including maintain speed, accelerate at a low rate, decelerate at a low rate, and decelerate at a medium rate. The first action can include one or more of lateral actions including maintain lane, left lane change, and right lane change. The control barrier functions can include lateral control barrier functions and longitudinal control barrier functions.

The longitudinal control barrier functions can be based on maintaining a distance between a vehicle and an in-lane following vehicle and an in-lane leading vehicle. The lateral control barrier functions can be based on lateral distances between a vehicle and other vehicles in adjacent lanes and steering effort based on avoiding the other vehicles in the adjacent lanes. The deep reinforcement learning neural network can approximate a Markov decision process. The Markov decision process can include a plurality of states, actions, and rewards. The behavior of the deep reinforcement learning neural network can be determined by exploring a state space to maximize an eventual future reward function at a given state. The control barrier function can calculate a minimally invasive safe action that will prevent violation of a safety constraint. The minimally invasive safe action can be applied to the output of the deep reinforcement learning neural network.

Further disclosed is a computer readable medium, storing program instructions for executing some or all of the above method steps. Further disclosed is a computer programmed for executing some or all of the above method steps, including a computer apparatus, programmed to determine a first action based on inputting sensor data to a deep reinforcement learning neural network, transform the first action to one or more first commands and determine one or more second commands by inputting the one or more first commands to control barrier functions. The one or more second commands can be transformed to a second action, a reward function can be determined by comparing the second action to the first action, and the one or more second commands can be output. A vehicle can be operated based on the one or more second commands. The vehicle can be operated by controlling vehicle powertrain, vehicle brakes, and vehicle steering. Training the deep reinforcement learning neural network can be based on the reward function. The first action can include one or more longitudinal actions including maintain speed, accelerate at a low rate, decelerate at a low rate, and decelerate at a medium rate. The first action can include one or more of lateral actions including maintain lane, left lane change, and right lane change. The control barrier functions can include lateral control barrier functions and longitudinal control barrier functions.

The computer apparatus can be further programmed to base the longitudinal control barrier functions on maintaining a distance between a vehicle and an in-lane following vehicle and an in-lane leading vehicle. The lateral control barrier functions can be based on lateral distances between a vehicle and other vehicles in adjacent lanes and steering effort based on avoiding the other vehicles in the adjacent lanes. The deep reinforcement learning neural network can approximate a Markov decision process. The Markov decision process can include a plurality of states, actions, and rewards. The behavior of the deep reinforcement learning neural network can be determined by exploring a state space to maximize an eventual future reward function at a given state. The control barrier function can calculate a minimally invasive safe action that will prevent violation of a safety constraint. The minimally invasive safe action can be applied to the output of the deep reinforcement learning neural network.

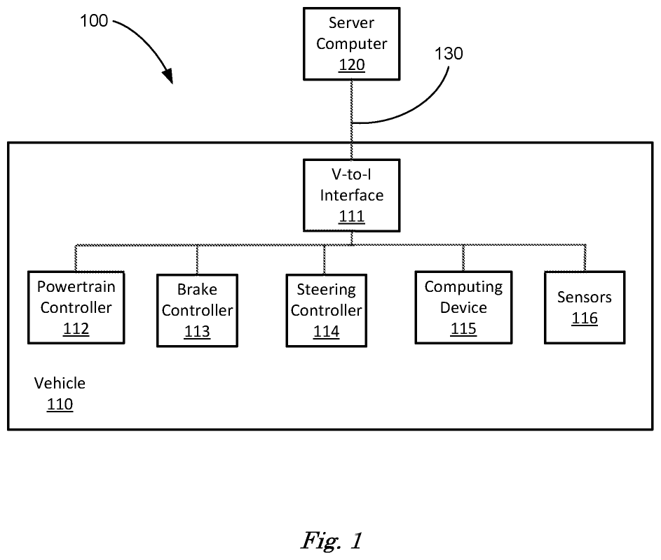

FIG. 1 is a diagram of an object detection system 100 that can be implemented with a machine such as a vehicle 110 operable in autonomous (“autonomous” by itself in this document means “fully autonomous”), semi-autonomous, and occupant piloted (also referred to as non-autonomous) mode. One or more vehicle 110 computing devices 115 can receive data regarding the operation of the vehicle 110 from sensors 116. The computing device 115 may operate the vehicle 110 in an autonomous mode, a semi-autonomous mode, or a non-autonomous mode.

The computing device 115 includes a processor and a memory such as are known. Further, the memory includes one or more forms of computer-readable media, and stores instructions executable by the processor for performing various operations, including as disclosed herein. For example, the computing device 115 may include programming to operate one or more of vehicle brakes, propulsion (e.g., control of acceleration in the vehicle 110 by controlling one or more of an internal combustion engine, electric motor, hybrid engine, etc.), steering, climate control, interior and/or exterior lights, etc., as well as to determine whether and when the computing device 115, as opposed to a human operator, is to control such operations.

The computing device 115 may include or be communicatively coupled to, e.g., via a vehicle communications bus as described further below, more than one computing devices, e.g., controllers or the like included in the vehicle 110 for monitoring and/or controlling various vehicle components, e.g., a powertrain controller 112, a brake controller 113, a steering controller 114, etc. The computing device 115 is generally arranged for communications on a vehicle communication network, e.g., including a bus in the vehicle 110 such as a controller area network (CAN) or the like; the vehicle 110 network can additionally or alternatively include wired or wireless communication mechanisms such as are known, e.g., Ethernet or other communication protocols.

Via the vehicle network, the computing device 115 may transmit messages to various devices in the vehicle and/or receive messages from the various devices, e.g., controllers, actuators, sensors, etc., including sensors 116. Alternatively, or additionally, in cases where the computing device 115 actually comprises multiple devices, the vehicle communication network may be used for communications between devices represented as the computing device 115 in this disclosure. Further, as mentioned below, various controllers or sensing elements such as sensors 116 may provide data to the computing device 115 via the vehicle communication network.

In addition, the computing device 115 may be configured for communicating through a vehicle-to-infrastructure (V-to-I) interface 111 with a remote server computer 120, e.g., a cloud server, via a network 130, which, as described below, includes hardware, firmware, and software that permits computing device 115 to communicate with a remote server computer 120 via a network 130 such as wireless Internet (WI-FI®)) or cellular networks. V-to-I interface 111 may accordingly include processors, memory, transceivers, etc., configured to utilize various wired and/or wireless networking technologies, e.g., cellular, BLUETOOTH® and wired and/or wireless packet networks. Computing device 115 may be configured for communicating with other vehicles 110 through V-to-I interface 111 using vehicle-to-vehicle (V-to-V) networks, e.g., according to Dedicated Short-Range Communications (DSRC) and/or the like, e.g., formed on an ad hoc basis among nearby vehicles 110 or formed through infrastructure-based networks. The computing device 115 also includes nonvolatile memory such as is known. Computing device 115 can log data by storing the data in nonvolatile memory for later retrieval and transmittal via the vehicle communication network and a vehicle to infrastructure (V-to-I) interface 111 to a server computer 120 or user mobile device 160.

As already mentioned, generally included in instructions stored in the memory and executable by the processor of the computing device 115 is programming for operating one or more vehicle 110 components, e.g., braking, steering, propulsion, etc., without intervention of a human operator. Using data received in the computing device 115, e.g., the sensor data from the sensors 116, the server computer 120, etc., the computing device 115 may make various determinations and/or control various vehicle 110 components and/or operations without a driver to operate the vehicle 110. For example, the computing device 115 may include programming to regulate vehicle 110 operational behaviors (i.e., physical manifestations of vehicle 110 operation) such as speed, acceleration, deceleration, steering, etc., as well as tactical behaviors (i.e., control of operational behaviors typically in a manner intended to achieve safe and efficient traversal of a route) such as a distance between vehicles and/or amount of time between vehicles, lane-change, minimum gap between vehicles, left-turn-across-path minimum distance, time-to-arrival at a particular location and intersection (without signal) minimum time-to-arrival to cross the intersection.

Controllers, as that term is used herein, include computing devices that typically are programmed to monitor and/or control a specific vehicle subsystem. Examples include a powertrain controller 112, a brake controller 113, and a steering controller 114. A controller may be an electronic control unit (ECU) such as is known, possibly including additional programming as described herein. The controllers may communicatively be connected to and receive instructions from the computing device 115 to actuate the subsystem according to the instructions. For example, the brake controller 113 may receive instructions from the computing device 115 to operate the brakes of the vehicle 110.

The one or more controllers 112, 113, 114 for the vehicle 110 may include known electronic control units (ECUs) or the like including, as non-limiting examples, one or more powertrain controllers 112, one or more brake controllers 113, and one or more steering controllers 114. Each of the controllers 112, 113, 114 may include respective processors and memories and one or more actuators. The controllers 112, 113, 114 may be programmed and connected to a vehicle 110 communications bus, such as a controller area network (CAN) bus or local interconnect network (LIN) bus, to receive instructions from the computing device 115 and control actuators based on the instructions.

Computing devices discussed herein such as the computing device 115 and controllers 112, 113, 114 include a processors and memories such as are known. The memory includes one or more forms of computer readable media, and stores instructions executable by the processor for performing various operations, including as disclosed herein. For example, a computing device or controller 112, 113, 114, 114 can be a generic computer with a processor and memory as described above and/or may include an electronic control unit (ECU) or controller for a specific function or set of functions, and/or a dedicated electronic circuit including an ASIC that is manufactured for a particular operation, e.g., an ASIC for processing sensor data and/or communicating the sensor data. In another example, computing device 115 may include an FPGA (Field-Programmable Gate Array) which is an integrated circuit manufactured to be configurable by a user. Typically, a hardware description language such as VHDL (Very High Speed Integrated Circuit Hardware Description Language) is used in electronic design automation to describe digital and mixed-signal systems such as FPGA and ASIC. For example, an ASIC is manufactured based on VHDL programming provided pre-manufacturing, whereas logical components inside an FPGA may be configured based on VHDL programming, e.g. stored in a memory electrically connected to the FPGA circuit. In some examples, a combination of processor(s), ASIC(s), and/or FPGA circuits may be included in a computer.

Sensors 116 may include a variety of devices known to provide data via the vehicle communications bus. For example, a radar fixed to a front bumper (not shown) of the vehicle 110 may provide a distance from the vehicle 110 to a next vehicle in front of the vehicle 110, or a global positioning system (GPS) sensor disposed in the vehicle 110 may provide geographical coordinates of the vehicle 110. The distance(s) provided by the radar and/or other sensors 116 and/or the geographical coordinates provided by the GPS sensor may be used by the computing device 115 to operate the vehicle 110 autonomously or semi-autonomously, for example.

The vehicle 110 is generally a land-based vehicle 110 capable of autonomous and/or semi-autonomous operation and having three or more wheels, e.g., a passenger car, light truck, etc. The vehicle 110 includes one or more sensors 116, the V-to-I interface 111, the computing device 115 and one or more controllers 112, 113, 114. The sensors 116 may collect data related to the vehicle 110 and the environment in which the vehicle 110 is operating. By way of example, and not limitation, sensors 116 may include, e.g., altimeters, cameras, LIDAR, radar, ultrasonic sensors, infrared sensors, pressure sensors, accelerometers, gyroscopes, temperature sensors, pressure sensors, hall sensors, optical sensors, voltage sensors, current sensors, mechanical sensors such as switches, etc. The sensors 116 may be used to sense the environment in which the vehicle 110 is operating, e.g., sensors 116 can detect phenomena such as weather conditions (precipitation, external ambient temperature, etc.), the grade of a road, the location of a road (e.g., using road edges, lane markings, etc.), or locations of target objects such as neighboring vehicles 110. The sensors 116 may further be used to collect data including dynamic vehicle 110 data related to operations of the vehicle 110 such as velocity, yaw rate, steering angle, engine speed, brake pressure, oil pressure, the power level applied to controllers 112, 113, 114 in the vehicle 110, connectivity between components, and accurate and timely performance of components of the vehicle 110.

Vehicles can be equipped to operate in both autonomous and occupant piloted mode. By a semi- or fully-autonomous mode, we mean a mode of operation wherein a vehicle can be piloted partly or entirely by a computing device as part of a system having sensors and controllers. The vehicle can be occupied or unoccupied, but in either case the vehicle can be partly or completely piloted without assistance of an occupant. For purposes of this disclosure, an autonomous mode is defined as one in which each of vehicle propulsion (e.g., via a powertrain including an internal combustion engine and/or electric motor), braking, and steering are controlled by one or more vehicle computers; in a semi-autonomous mode the vehicle computer(s) control(s) one or more of vehicle propulsion, braking, and steering. In a non-autonomous mode, none of these are controlled by a computer.

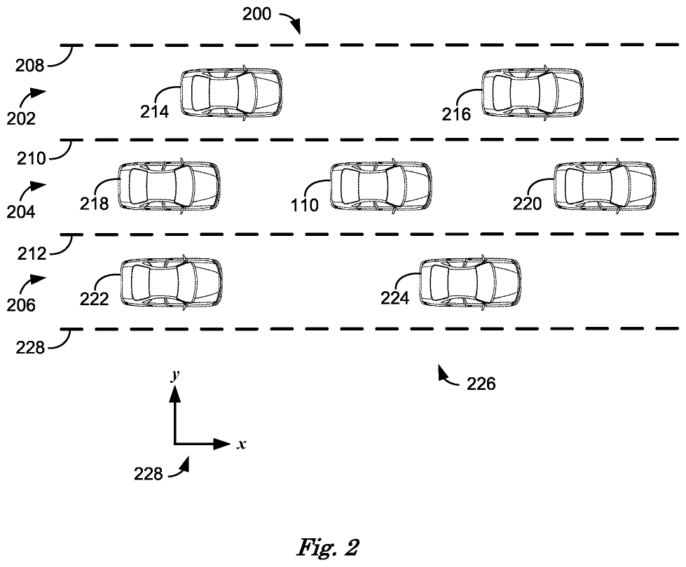

FIG. 2 is a diagram of an example roadway 200. Roadway 200 includes traffic lanes 202, 204, 206 defined by lane markers 208, 210, 212, 228. Roadway 200 includes a vehicle 110. Vehicle 110 acquires data from sensors 116 regarding the vehicle's 110 location within the roadway 200 and the locations of vehicles 214, 216, 218, 220, 222, 224, referred to collectively as surrounding vehicles 226. Surrounding vehicles 226 include to input to a DRL agent and a CBF to determine an action. Surrounding vehicles 226 are also labeled as rear left vehicle 214, front left vehicle 216, rear center or in-lane following vehicle 218, front center or in-lane leading vehicle 220, rear right vehicle 222, and front right vehicle 224, based on their relationship to host vehicle 110.

Sensor data regarding the location of the vehicle 110 and the locations of the surrounding vehicles 226 is referred to as affordance indicators. Affordance indicators are determined with respect to roadway coordinate axes 228. Affordance indicators include vehicle 110 y position with respect to roadway 200 coordinate system, velocity of vehicle 110 with respect to roadway coordinate system, relative x-position of surrounding vehicles 226, relative y-position of surrounding vehicle 226 and velocities of surrounding vehicles with respect to the roadway coordinate system. A vector that includes all the affordance indicators is the state s. Additional affordance indicators can include heading angles and accelerations for each of the surrounding vehicles 226.

A DRL agent included in vehicle 110 can input the state s of affordance indicators and output a high-level action a. A high-level action a can include a longitudinal action and a lateral action. Longitudinal actions, aₓ, include maintain speed, accelerate at a low rate, for example 0.2 g, decelerate at a low rate, for example 0.2 g, and decelerate at a medium rate, for example 0.4 g, where g is the acceleration constant due to gravity. Lateral actions, a_{y}, include maintain lane, left lane change, and right lane change. A high-level action a is a combination of a longitudinal and a lateral action, i.e. a=aₓ×a_{y}. The action a therefore includes 12 possible actions that the DRL agent can select from based on the input affordance indicators. Any suitable path follower algorithm can be implemented, e.g., in a computing device 115, to convert a high-level action into low-level commands that can be translated by a computing device 115 into commands that can be output to vehicle controllers 112, 113, 114 for operating a vehicle. Various path follower algorithms and output commands are known. For example, longitudinal commands are acceleration requests that can be translated into powertrain and braking commands. Lateral actions can be translated into steering commands using a gain scheduled state feedback controller. A gain scheduled state feedback controller is a controller that assumes linear behavior of the control feedback variable when the control feedback variable assumes a value close to the value of the control point to permit closed loop control over a specified range of inputs. A gain scheduled state feedback controller can convert lateral motion and limits on lateral accelerations into turn rates based on wheel angles.

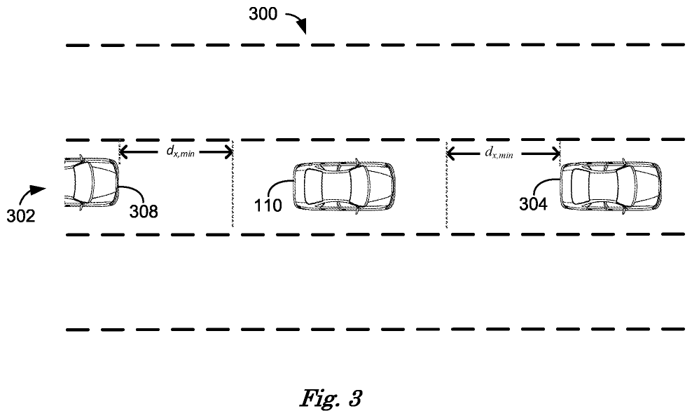

FIG. 3 is a diagram of a traffic scene 300 illustrating longitudinal control barrier functions. Longitudinal control barrier functions are based on maintaining a distance between a vehicle and an in-lane following vehicle and an in-lane leading vehicle. Longitudinal control barrier functions are defined in terms of distances between vehicles 110, 308, 304 in a traffic lane 302. A minimum longitudinal distance d_{x,min} is the minimum distance between a vehicle 110 and a rear center or in-lane following vehicle 308 and a front center or in-lane leading vehicle 304. The longitudinal virtual boundary hₓ and forward virtual boundary speed \dot{h}ₓ are determined by the equations:

$${h}_{x} = \vert {x}_{T} \vert - sgn ( {x}_{T} ) {k}_{v} {v}_{H} - {d}_{x , min} - \frac{{L}_{H}}{2} - \frac{{L}_{T}}{2} \qquad ( 1 )$$

$${\dot{h}}_{x} ( α ) = - sgn ( {x}_{T} ) ( {k}_{v} + \frac{{v}_{H}}{{dec}_{max}} ) ℊα + sgn ( {x}_{T} ) ( {v}_{T} cos {θ}_{T} - {v}_{H} cos {θ}_{H} ) \qquad ( 2 )$$

$${k}_{v} = \{ \begin{matrix}{k}_{v 0} = max ( \frac{{v}_{H} - {v}_{T}}{{dec}_{max}} , 1 ) & \vert {y}_{T} \vert < {W}_{H} \\ {k}_{v 0} exp ( - λ ( \vert {y}_{T} \vert - {W}_{H} ) ) & \vert {y}_{T} \vert \geq {W}_{H}\end{matrix} \qquad ( 3 )$$

Where x_{T} is the location of the target vehicle 304, 308 in the x-direction, y_{T} is the location of the target vehicle 304, 308 in the y-direction, kᵥ is the time headway i.e., an estimated time for the host vehicle 110 to reach the target vehicle 308, 304 in the longitudinal direction, v_{H} is the velocity of the host vehicle 110 and

$$\frac{{L}_{H}}{2} , \frac{{L}_{T}}{2}$$

are the lengths of the host vehicle 110 and the target vehicles 308, 304, respectively. The variable kᵥ is a time headway, i.e., an estimated time for the host vehicle 110 to reach the target vehicle 304, 308 in the longitudinal direction, decₘₐₓ is a maximum deceleration of the host vehicle 110, and kᵥ₀ is a maximum time headway determined by the speeds v_{H}, v_{T} of the host vehicle 110 and the target vehicle 304, 308. θ_{H}, θ_{T} are respective heading angles of the host vehicle 110 and the target vehicle 304, 308, A is a predetermined decay constant and W_{H} is the width of the host vehicle 110. The computing device 115 can determine the decay constant λ based on empirical testing.

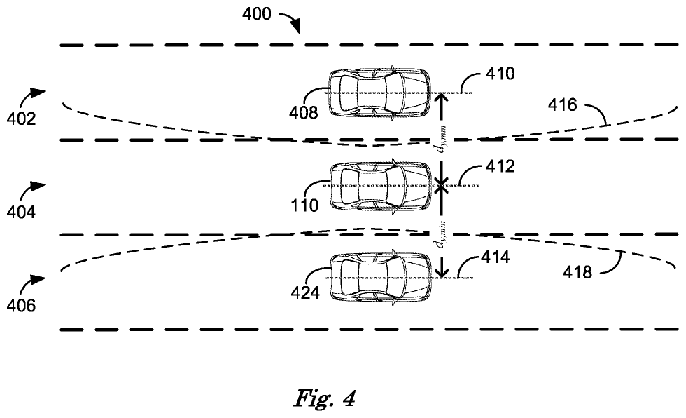

FIG. 4 is a diagram of a traffic scene 400 illustrating lateral control barrier functions. Lateral barrier functions are based on lateral distances between a vehicle and other vehicles in adjacent lanes and steering effort based on avoiding the other vehicles in the adjacent lanes. In traffic scene 400, a host vehicle 110 in a first traffic lane 404 is separated by at least a minimum lateral distance d_{y,min} from target vehicles 408, 424 in adjacent traffic lanes 402, 406, respectively. Minimum lateral distances d_{y,min} are measured with respect to vehicle 110, 408, 424 centerlines 412, 410, 414, respectively. The lateral barriers 416, 418 determine the maximum lateral acceleration permitted when the host vehicle 110 changes lanes. Right virtual boundary h_{R}, a right virtual boundary speed \dot{h}_{R}, and a right virtual boundary acceleration \ddot{h}_{R} are determined by the equations:

$${h}_{R} = - {y}_{T} - {d}_{y , min} + {c}_{b} {x}_{T}^{2} \qquad ( 4 )$$

$${\dot{h}}_{R} = {v}_{H} sin {θ}_{H} - {v}_{T} sin {θ}_{T} + 2 {c}_{b} {x}_{T} ( {v}_{T} cos {θ}_{T} - {v}_{H} cos {θ}_{H} ) \qquad ( 5 )$$

$${\ddot{h}}_{R} ( δ ) = - ( cos {θ}_{H} + 2 {c}_{b} {x}_{T} sin {θ}_{H} ) \frac{{v}_{H}^{2} δ}{{L}_{H}} + ( sin {θ}_{H} + 2 {c}_{b} {x}_{T} cos {θ}_{H} ) {ℊα}_{0} + 2 {{c}_{b} ( {v}_{T} cos {θ}_{T} - {v}_{H} cos {θ}_{H} )}^{2} \qquad ( 6 )$$

$${c}_{b} = max ( {c}_{0} - {ℊ}_{b} ( {v}_{H} - {v}_{T} ) , {c}_{b , min} ) \qquad ( 7 )$$

Where y_{T} is the y location of the target vehicle 408, 424, d_{y,min} is a predetermined minimum lateral distance between the host vehicle 110 and the target vehicle 408, 424, and θ_{H}, θ_{T} are respective heading angles of the host vehicle 110 and the target vehicle 408, 424. The variable c_{b} is a bowing coefficient that determines the curvature of the virtual boundary h_{R}·c₀ is a predetermined default bowing coefficient. g_{b} is a tunable constant that controls the effect on the speeds v_{H}, v_{T} on the bowing coefficient, and c_{b,min} is a predetermined minimum bowing coefficient. The predetermined values d_{y,min},c₀,c_{b,min} can be determined by the manufacturer according to empirical testing of virtual vehicles in a simulation model, such as Simulink, a software simulation program produced by MathWorks, Inc. Natick, Mass. 01760. For example, the minimum bowing coefficient c_{b,min} can be determined by solving a constraint equation described below in a virtual simulation for a specified constraint value. The bowing is meant to reduce the steering effort required to satisfy the collision avoidance constraint when the target vehicle 408, 424 is far away from the host vehicle 110. The minimum lateral distance d_{y,min} is only enforced when the host vehicle 110 is operating alongside the target vehicles 408, 424.

Left virtual boundary h_{L}, a left virtual boundary speed \dot{h}_{L}, and a left virtual boundary acceleration \ddot{h}_{L} are determined in similar fashion as above by the equations:

$${h}_{L} = {y}_{T} - {d}_{y , min} + {c}_{b} {x}_{T}^{2} \qquad ( 8 )$$

$${\dot{h}}_{L} = {v}_{T} sin {θ}_{T} - {v}_{H} sin {θ}_{H} + 2 {c}_{b} {x}_{T} ( {v}_{T} cos {θ}_{T} - {v}_{H} cos {θ}_{H} ) \qquad ( 9 )$$

$${\ddot{h}}_{L} ( δ ) = ( cos {θ}_{H} - 2 {c}_{b} {x}_{T} sin {θ}_{H} ) \frac{{v}_{H}^{2} δ}{{L}_{H}} - ( sin {θ}_{H} - 2 {c}_{b} {x}_{T} cos {θ}_{H} ) {ℊα}_{0} + 2 {{c}_{b} ( {v}_{T} cos {θ}_{T} - {v}_{H} cos {θ}_{H} )}^{2} \qquad ( 10 )$$

Where y_{T}, d_{y,min}, c_{b}, c₀, c_{b,min}, g_{b}, θ_{H}, θ_{T} and v_{H}, v_{T} are as defined above with respect to the right virtual boundary. As defined above, minimum lateral distance d_{y,min} is only enforced when the host vehicle 110 is operating alongside the target vehicles 408, 424.

The computing device 115 can determine lane-keeping virtual boundaries that define virtual boundaries for the traffic lanes 202, 204, 206. The lane-keeping virtual boundaries can be described with boundary equations:

$${h}_{LK} = [ \begin{matrix}3 {w}_{l} - \frac{{w}_{H}}{2} - {y}_{H} \\ {y}_{H} - \frac{{w}_{H}}{2}\end{matrix} ] \qquad ( 11 )$$

$${\dot{h}}_{LK} = [ \begin{matrix}- {v}_{H} {θ}_{H} \\ {v}_{H} {θ}_{H}\end{matrix} ] \qquad ( 12 )$$

$${\ddot{h}}_{LK} ( δ ) = [ \begin{matrix}- \frac{{v}_{H}^{2} cos {θ}_{H} δ}{{L}_{H}} \\ \frac{{v}_{H}^{2} cos {θ}_{H} δ}{{L}_{H}}\end{matrix} ] \qquad ( 13 )$$

Where y_{H} is the y-coordinate of the host vehicle 110 of a coordinates system fixed relative to the roadway 205, with the y-coordinate of the right-most traffic lane marker being 0, W_{H} is the width of the host vehicle 105, L_{H} is the length of the host vehicle 110, and wₗ is the width of the traffic lane.

The computing device 115 can determine a specified steering angle and longitudinal acceleration δ_{CBF}, α_{CBF} with a conventional quadratic program algorithm. A “quadratic program” algorithm is an optimization program that minimizes a cost function J for iteratively values of δ_{CBF}, α_{CBF}. The computing device 115 can determine a lateral left quadratic program QP_{yL}, a lateral right quadratic program QP_{yR}, and a longitudinal quadratic program QPₓ, each with a respective cost function J_{yL}, J_{yR}, Jₓ.

The computing device 115 can determine the lateral left cost function J_{yL} for lateral left quadratic program QP_{yL}:

$${J}_{yL} = \begin{matrix}[ {δ}_{CBF , L} & s & {s}_{a} ] {Q}_{y} [ \begin{matrix}{δ}_{CBF , L} \\ s \\ {s}_{a}\end{matrix} ]\end{matrix} \qquad ( 14 )$$

$$s . t . {\ddot{h}}_{L , T} ( {δ}_{0} + {δ}_{CBF , L} ) + {l}_{1 , y} {\dot{h}}_{L , T} + {l}_{0 , y} {h}_{L , T} \geq 0 \qquad ( 15 )$$

$${\ddot{h}}_{y , i} ( {δ}_{0} + {δ}_{CBF , L} ) + {l}_{1 , y} {\dot{h}}_{y , i} + {l}_{0 , y} {h}_{y , i} \geq 0 , i ∈ Y \qquad ( 16 )$$

$${\ddot{h}}_{L , LK} ( {δ}_{0} + {δ}_{CBF , L} ) + {l}_{1 , LK} {\dot{h}}_{L , LK} + {l}_{0 , LK} {h}_{L , LK} + [ \begin{matrix}1 \\ 1\end{matrix} ] s \geq 0 \qquad ( 17 )$$

$${δ}_{min} - {δ}_{0} \leq {δ}_{CBF , L} + {s}_{a} \qquad ( 18 )$$

$${δ}_{CBF , L} - {s}_{a} \leq {δ}_{max} - {δ}_{0} \qquad ( 19 )$$

Where Q_{y} is a matrix that includes values that minimize the steering angle δ_{CBF,L}, i is an index for the set of Y targets other than the target vehicle 226, s, sₐ, are what are conventionally referred to as “slack variables,” i.e., tunable variables that allow violation of one or more of the constraint values to generate the equality for J_{yL}, the “T” subscript refers to the target vehicles 226, and the “LK” subscript refers to values for the lane-keeping virtual boundaries described above. δ₀ is the DRL/path follower steering angle and δₘᵢₙ,δₘₐₓ are minimum and maximum steering angles that the steering component can attain. The path follower is discussed in relation to FIG. 6, below. The variables l₀,l₁ are predetermined scalar values that provide real, negative roots to the characteristic equations associated with the second order dynamics (s²+l₁s+l₀=0).

The computing device 115 can determine the lateral right cost function J_{yR} for the lateral right quadratic program QP_{yR}:

$${J}_{yR} = \begin{matrix}[ {δ}_{CBF , R} & s & {s}_{a} ] {Q}_{y} [ \begin{matrix}{δ}_{CBF , R} \\ s \\ {s}_{a}\end{matrix} ]\end{matrix} \qquad ( 20 )$$

$$s . t . {\ddot{h}}_{R , T} ( {δ}_{0} + {δ}_{CBF , R} ) + {l}_{1 , y} {\dot{h}}_{R , T} + {l}_{0 , y} {h}_{R , T} \geq 0 \qquad ( 21 )$$

$${\ddot{h}}_{y , i} ( {δ}_{0} + {δ}_{CBF , R} ) + {l}_{1 , y} {\dot{h}}_{y , i} + {l}_{0 , y} {h}_{y , i} \geq 0 , i ∈ Y \qquad ( 22 )$$

$${\ddot{h}}_{R , LK} ( {δ}_{0} + {δ}_{CBF , R} ) + {l}_{1 , LK} {\dot{h}}_{R , LK} + {l}_{0 , LK} {h}_{R , LK} + [ \begin{matrix}1 \\ 1\end{matrix} ] s \geq 0 \qquad ( 23 )$$

$${δ}_{min} - {δ}_{0} \leq {δ}_{CBF , R} + {s}_{a} \qquad ( 24 )$$

$${δ}_{CBF , R} - {s}_{a} \leq {δ}_{max} - {δ}_{0} \qquad ( 25 )$$

The computing device 115 can solve the quadratic programs QP_{yL}, QP_{yR} for the steering angles δ_{CBF,L},δ_{CBF,R} and can determine the supplemental steering angle δ_{CBF} as one of these determined steering angles δ_{CBF,L},δ_{CBF,R}. For example, if one of the steering angles δ_{CBF,L},δ_{CBF,R} is infeasible and the other is feasible, the computing device 115 can determine the supplemental steering angle δ_{CBF} as the feasible one of δ_{CBF,L},δ_{CBF,R}. The constraints (20)-(22) have a dependence on δ₀, i.e., the steering angle requested by the path follower. If δ₀ is sufficient to satisfy the constraints, δ_{CBF}=0. If δ₀ is insufficient, δ_{CBF} is used to supplement it so that the constraints are satisfied. Therefore, δ_{CBF} can be considered as a supplemental steering angle that is used in addition to the nominal steering angle δ₀. In the context of QP_{yL} and QP_{yR}, a steering angle δ is “feasible” if the steering component 120 can attain the steering angle δ while satisfying the constraints for QP_{yL} or for QP_{yR}, shown in the above Expressions. A steering angle is “infeasible” if the steering component 120 cannot attain the steering angle δ without violating at least one of the constraints for QP_{yL} or for QP_{yR}, shown in the above expressions. The solution to the quadratic programs QP_{yL}, QP_{yR} can be infeasible as described above, and the computer 110 can disregard infeasible steering angle determinations.

If both δ_{CBF,L},δ_{CBF,R} are feasible, the computing device 115 can select one of the steering angles δ_{CBF,L},δ_{CBF,R} as the determined supplemental steering angle δ_{CBF} based on a set of predetermined conditions. The predetermined conditions can be a set of rules determined by, e.g., a manufacturer, to determine which of the steering angles δ_{CBF,L},δ_{CBF,R} to select as the determined supplemental steering angle δ_{CBF}. For example, if both δ_{CBF,L},δ_{CBF,R} are feasible, the computing device 115 can determine the steering angle δ_{CBF} as a previously determined one of δ_{CBF,L},δ_{CBF,R}. That is, if the computing device 115 in a most recent iteration selected δ_{CBF,L} as the determined supplemental steering angle δ_{CBF}, the computing device 115 can select the current δ_{CBF,L} as the determined supplemental steering angle δ_{CBF}. In another example, if a difference between the cost functions J_{yL},J_{yR} are below a predetermined threshold (e.g., 0.00001), the computing device 115 can have a default selection of the supplemental steering angle δ_{CBF}, e.g., δ_{CBF,L} can be the default selection for the supplemental steering angle δ_{CBF}. The safe steering angle δ_{S} is then set as δ_{S}=δ₀+δ_{CBF}.

If both δ_{CBF,L},δ_{CBF,R} are infeasible, the computing device 115 can determine the cost functions J_{yL},J_{y,R} with a longitudinal constraint replacing the lateral constraint. That is, in the expressions with h_{y,i} above, the computing device 115 can use the longitudinal virtual boundary equations h_{x,i} instead. Then, the computing device 115 can determine the steering angle δ_{CBF} based on whether the values for δ_{CBF,L},δ_{CBF,R} are feasible, as described above. If δ_{CBF,L},δ_{CBF,R} are still infeasible, the computing device 115 can apply a brake to slow the vehicle 110 and avoid the target vehicles 226.

To determine the acceleration α_{CBF}, the computing device 115 can determine a longitudinal quadratic program QPₓ:

α_{CBF}=arg min α_{CBF}² (26)

s.t.\dot{h}_{x,i}(α₀+α_{CBF})+l_{0,x}h_{x,i}≥0,iϵX (27)

Where argmin( ) is the argument minimum function, as is known, that determines the minimum of the input subject to one or more constraints, and X is the set of target vehicles 226. The variables \dot{h}_{x,i}, h_{x,i}, and l_{0,x} are as defined above in relation to equations (1) and (2).

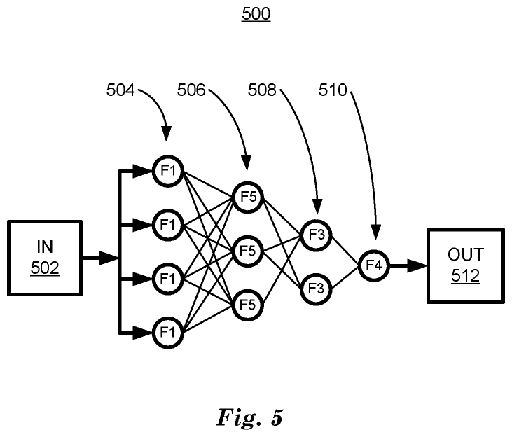

FIG. 5 is a diagram of a DRL agent 500. DRL agent 500 is a deep neural network that inputs a vehicle state s (IN) 502 and outputs an action a (OUT) 512. DRL agent includes layers 504, 506, 508, 510 that include fully connected processing neurons F1, F2, F3, F4. Each processing neuron is connected to either an input value or output from one or more neurons F1, F2, F3 in a preceding layer 504, 506, 508. Each neuron F1, F2, F3, F4 can determine a linear or non-linear function of the inputs and output the result to the neurons F2, F3, F4 in a succeeding layer 506, 508, 510. A DRL agent 500 is trained by determining a reward function based on the output and inputting the reward function to the layers 504, 506, 508, 510. The reward function is used to determined weights that govern the linear or non-linear functions determined by the neurons F1, F2, F3, F4.

A DRL agent 500 is a machine learning program that combines reinforcement learning and deep neural networks. Reinforcement learning is a process whereby an DRL agent 500 learns how to behave in its environment by trial and error. The DRL agent 500 uses its current state s (e.g., road/traffic conditions) as an input, and selects an action a (e.g. accelerate, change lanes etc.) to take. The action results in the DRL agent 500 moving into a new state, and either being rewarded or penalized for the action it took. This process is repeated many times and by trying to maximize its potential future reward, a DRL agent 500 learns how to behave in its environment. A reinforcement learning problem can be expressed as a Markov Decision Process (MDP). An MDP consists of a 4-tuple (S, A, T, R), where S is the state space, A is the action space, T:S×A→S′ is the state transition function, and R:S×A×S′→ [symbol] is the reward function. The objective of the MDP is to find an optimal policy π* that maximizes the potential future reward:

$${π}^{*} = {arg max}_{π} {R}^{π} = {r}_{0} + γ {r}_{1} + {γ}^{2} {r}_{2} + … \qquad ( 28 )$$

Where γ is a discount factor that discounts rewards r₁ in the future. In DRL agent 500, a deep neural network is used to approximate the MDP, so that a state transition function is not required. This is useful when either the state space and/or the action space is large or continuous. The mechanism by which the deep neural network approximates the MDP is by minimizing the loss function at step i:

$${L}_{i} ( {w}_{i} ) = {𝔼}_{s , a , r , {s}^{′}} [ r + γ {max}_{{a}^{′}} Q ( {s}^{′} , {a}^{′} , {w}^{-} ) - Q ( s , a , {w}_{i} ) ] \qquad ( 29 )$$

Where w are the weights of the neural network, s is the current state, a is the current action, r is the reward determined for the current action, s′ is the state reached by taking action a in state s, Q (s, a, wᵢ) is the estimate of the value of action a at state s, and [symbol] is the expected difference between the determined value and the estimated value. The weights of the neural network are updated by gradient descent.

$$Δ w = β ( r + γ {max}_{a} \hat{q} ( {s}^{′} , a , \overline{w} ) - \hat{q} ( s , a , w ) ) {∇}_{w} \hat{q} ( s , a , w ) \qquad ( 30 )$$

Where β is the size of the step and w̅ is the fixed target parameter that is updated periodically, and ∇_{w}\hat{q}(s, a, w) is the gradient with respect to the weights w. Fixed target parameter w̅ is used instead of w in equation (29) is to improve stability of the gradient descent algorithm.

FIG. 6 is an example vehicle path system 600. Vehicle path system 600 is configured to train DRL 604. Affordance indicators (AI) 602 are determined by inputting data from vehicle sensors 116 as discussed above in relation to FIG. 2 and input to DRL 604. Affordance indicators 602 are the current state s input to DRL 604. DRL 604 outputs a high-level action a 606 in response to input affordance indicators 602 as discussed in relation to FIG. 2, above. High-level actions a 606 are input to path follower algorithm (PF) 608. Path follower algorithm 608 uses gain scheduled state feedback control to determine vehicle powertrain, steering and brake commands that can control vehicle 110 to execute the high-level actions a output by DRL 604. Vehicle powertrain, steering and brake commands are output by path follower algorithm 608 as low-level commands 610.

Low level commands 610 are input to control barrier functions (CBF) 612. Control barrier functions 612 determine boundary equations (1)-(13) as discussed above in relation to FIGS. 3 and 4. Control barrier functions 612 determine whether the low-level commands 610 output by path follower 608 will result in safe operation of the vehicle 110. If the low-level commands 610 are safe, meaning that execution of the low-level command 610 would not result in vehicle 110 exceeding a lateral or longitudinal barrier, the low-level command 610 can be output from control barrier functions 612 unchanged. In examples where the low-level commands 610 would cause acceleration or steering commands that would cause vehicle 110 to exceed a lateral or longitudinal barrier, the command can be modified using quadratic program algorithms (equations (14)-(27)) as discussed above in relation to FIG. 5, for example. In response to input low-level commands 610 from path follower 608, along with input affordance indicators 602, control barrier functions 612 outputs vehicle commands (OUT) 614 based on the input low-level commands 610, where the low-level command 610 is either unchanged or modified. The vehicle commands 614 are passed to a computing device 115 in vehicle 110 to be translated into commands to controllers 112, 113, 114 that control vehicle powertrain, steering and brakes.

Vehicle commands 614 translated into commands to controllers 112, 113, 114 that control vehicle powertrain, steering and brakes cause vehicle 110 to operate in the environment. Operating in the environment will cause the location and orientation of vehicle 110 to change in relation to the roadway 200 and surrounding vehicles 226. Changing the relationship to the roadway 200 and surrounding vehicle 226 will change the sensor data acquired by vehicle sensors 116.

Vehicle commands 614 are also communicated to action translator (AT) 616 for translation from vehicle commands 614 back into high-level commands. The high-level commands can be compared to the original high-level commands 606 output by the DRL agent 604 to determine reward functions that are used to train DRL 604. As discussed above in relation to FIG. 5, the state space s of possible traffic situations is large and continuous. It is not likely that the initial training of a DRL agent 604 will include all the traffic situations to be encountered by a vehicle 110 operating in the real world. Continuous, ongoing training using reinforcement learning will permit a DRL agent 604 to improve its performance while control barrier functions 612 prevent the vehicle 110 from implementing unsafe commands from DRL agent 604 as it is trained. The DRL agent 604 outputs a high-level command 606 once per second and the path follower 608 and control barrier functions 612 update 10 times per second.

A reward function is used to train the DRL agent 604. The reward function can include four components. The first component compares the velocity of the vehicle with the desired velocity output from the control barrier functions 612 to determine a velocity reward rᵥ:

r_{V}=fᵥ(v_{H},v_{D}) (31)

Where v_{H} is the velocity of the host vehicle 110, v_{D} is the desired velocity and fᵥ is a function the determines the size of the penalty for deviating from the desired velocity.

The second component is a measure of the lateral performance of the vehicle 110, lateral reward rₗ:

rₗ=fₗ(y_{H},y_{D}) (32)

Where y_{H} is the lateral position of the host vehicle 110, y_{D} is the desired lateral position and fₗ is a function that determines the size of the penalty for deviating from the desired position.

The third component of the reward function is a safety component rₛ that determines how safe the action a is, by comparing it to the safe action output by the control barrier functions 612:

rₛ=fₓ(aₓ,āₓ)+f_{y}(a_{y},ā_{y}) (33)

Where aₓ is the longitudinal action selected by the DRL agent 604, āₓ is the safe longitudinal action output by the control barrier functions 612, a_{y} is the lateral action selected by the DRL agent 604, ā_{y} is the safe lateral action output by the control barrier functions 612 and fₓ and fₓ are functions that determine the size of the penalty for unsafe longitudinal and lateral actions, respectively.

The fourth component of the reward function is a penalty on collisions:

r_{c}=f_{c}(C) (34)

Where C is a Boolean that is true if a collision occurs during the training episode and f_{c} is a function that determines the size of the penalty for collisions. Note that the collision penalty is used only in the case where there is no control barrier functions 612 to act as a safety filter. This would be true only in examples where the DRL agent 604 is being trained using simulated or on-road data, for example. More components can be added to the reward function to match a desired performance objective by adding reward functions structured similarly to reward functions determined according to equations (31)-(34).

In some examples, the control barrier functions 612 safety filter can be compared with a rule-based safety filter. Rule-based safety filters are machine learning systems that use a series of user-supplied conditional statements to test the low-level commands. For example, a rule-based safety filter can include a statement such as “if the host vehicle 110 is closer than x feet from another vehicle and host vehicle speed is greater than v miles per hour, then apply brakes to slow vehicle by m miles per hour”. A rule-based safety filter evaluates included statements and when the “if” portion of the statement evaluates to “true”, the “then” portion is output. Rule-based safety filters depend upon user input to anticipate possible unsafe conditions but can add redundancy to improve safety in a vehicle path system 600.

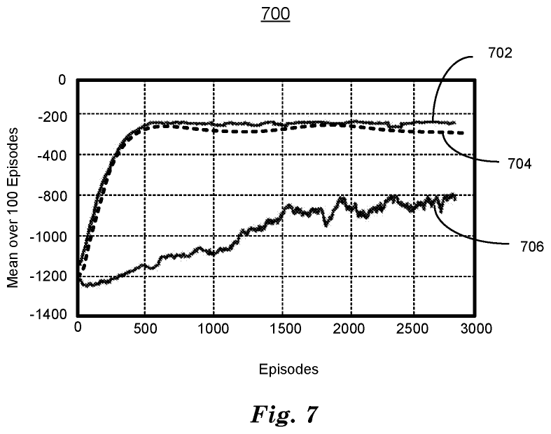

FIG. 7 is a diagram of a graph 700 illustrating training of a DRL agent 604. DRL agent 604 is trained using simulated data, where the affordance indicators 602 input to the vehicle path system 600 are determined by a simulation program such as Simulink. The affordance indicators 602 are updated based on vehicle commands 614 output to the simulation program. The DRL agent 604 is trained based on a plurality of episodes that include 200 seconds of highway driving. In each episode, the surrounding environment, i.e., the density, speed, and location of surrounding vehicles 226 is randomized.

Graph 700 plots the number of episodes processed by DRL agent 604 on the x-axis versus the mean over 100 episodes of the reward function rᵥ+rₗ+rₛ+r_{c} on the y-axis. An episode consists of 200 seconds of highway driving or until a simulated collision occurs. Each episode is initialized randomly. Graph 700 plots training performance without using a control barrier functions 612 safety filter on line 706, with the control barrier functions 612 on line 702 and with a rule-based safety filter on line 704. While learning to output vehicle commands 614 without a safety filter, illustrated by line 706 of graph 700, the DRL agent outputs high-level commands 606 that are translated to vehicle commands 614 that result in many collisions initially and slowly improves without learning to control vehicle 110 safely. With the control barrier functions 612 (line 702) the DRL agent 604 emits high-level commands 606 that are translated to vehicle commands 614, the time required to learn acceptable vehicle operation behavior is reduced significantly. With the control barrier functions 612, the negative collision reward is reduced, meaning vehicle operation is safer, because the control barrier functions 612 prevents collisions in examples where the DRL agent 604 makes an unsafe decision. Without the control barrier functions 612, structuring the collision reward function in a way that guides the DRL agent 604 to make safe vehicle operation decisions is difficult. Line 704 shows DRL agent 604 training performance using a rule-based safety filter. Rule-based safety filters do not appreciably increase training performance and can result in exceedingly conservative vehicle operation i.e., a host vehicle 110 operating with a rule-based safety filter can take much longer to reach a destination that a host vehicle 110 operating with a control barrier functions 612.

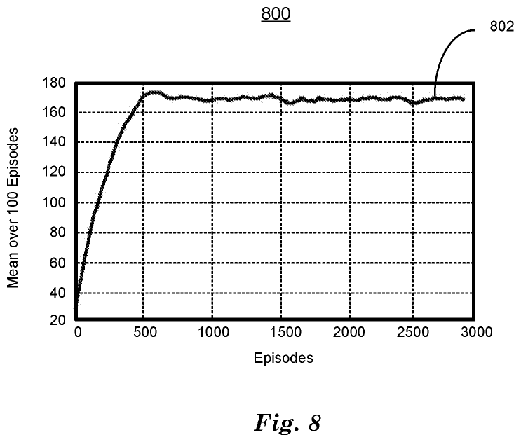

FIG. 8 is a diagram of a graph 800 illustrating the number of episodes on the x-axis versus the mean over 100 episodes of the number of safe vehicle commands 614 output in response to high level commands 606 output by DRL agent 604 on the y-axis. In an episode that is 200 seconds long, 20 of the high-level commands 606 or vehicle actions a are random explorations, so the maximum number of safe actions a selected by DRL agent 604 is 180. Line 802 of graph 800 illustrates that the DRL Agent 604 learns to operate more safely as time progresses.

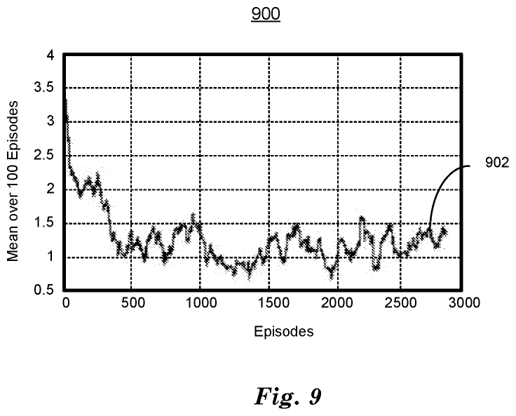

FIG. 9 is a diagram of a graph 900 illustrating the number of episodes on the x-axis versus the mean over 100 episodes of the sum of the norm of acceleration corrections over 200 seconds of highway operation. The number of acceleration corrections 902 and the severity of those corrections both decrease over time, meaning that the DRL agent 604 is learning to operate the vehicle 110 safely.

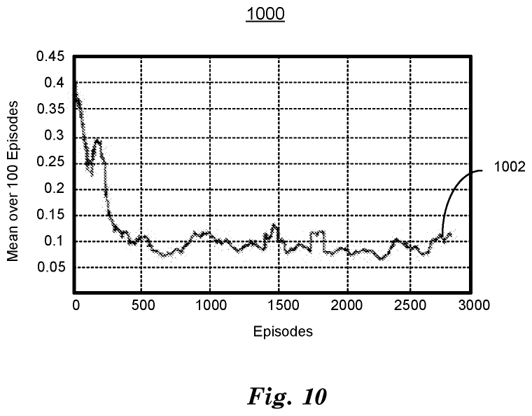

FIG. 10 is a diagram of a graph 900 illustrating the number of episodes on the x-axis versus the mean over 100 episodes of the sum of the norm of steering corrections over 200 seconds of highway operation. The number of steering corrections 1002 and the severity of those corrections both decrease over time, meaning that the DRL agent 604 is learning to operate the vehicle 110 safely. Because the reward function as shown in FIG. 7 is higher with the control barrier functions 612 than without the control barrier functions 612, the addition of the acceleration corrections 902 and steering corrections 1002 does not cause vehicle operation to become too conservative.

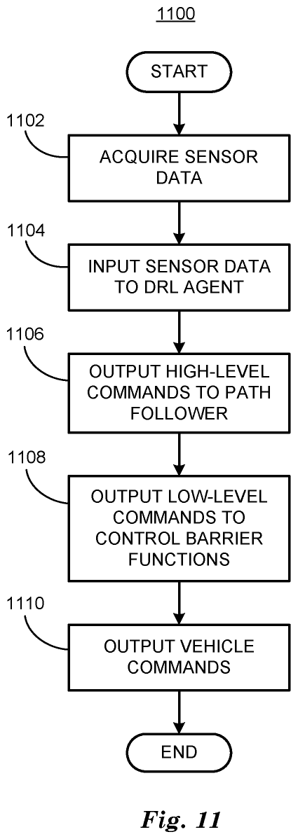

FIG. 11 is a diagram described in relation to FIGS. 1-10, of a process 1100 for operating a vehicle 110 based on a vehicle path system 600. Process 1100 can be implemented by a processor of computing device 115, taking as input information from sensors 116, and outputting vehicle commands 614, for example. Process 1100 includes multiple blocks that can be executed in the illustrated order. Process 1100 could alternatively or additionally include fewer blocks or can include the blocks executed in different orders. Process 1100 can be implemented as programming in a computing device 115 included in a vehicle 110, for example.

Process 1100 begins at block 1102, where sensors 116 included in a vehicle can input data from an environment around a vehicle. The sensor data can include video data that can be processed using deep neural network software programs included in computing device 115 that detect surrounding vehicle 226 in the environment around vehicle 110, for example. Deep neural network software programs can also detect traffic lane markers 208, 210, 212, 228 and traffic lanes 202, 204, 206 to determine vehicle location and orientation with respect to roadway 200, for example. Vehicle sensors 116 can also include a global positioning system (GPS) and an inertial measurement unit (IMU) that supply vehicle location, orientation, and velocity, for example. The acquired vehicle sensor data is processed by computing device 115 to determine affordance indicators 602.

At block 1104 affordance indicators 602 based on vehicle sensor data are input to a DRL agent 604 included in a vehicle path system 600. The DRL agent 604 determines high-level commands 606 in response to the input affordance indicators 602 as discussed in relation to FIGS. 5 and 6, above and outputs them to a path follower 608.

At block 1106 a path follower 608 determines low-level commands 610 based on the input high-level commands 606 according to equations (13)-(26) as discussed above in relation to FIGS. 5 and 6, above and outputs them to control barrier functions 612.

At block 1108 control barrier functions 612 determine whether the low-level commands 610 are safe. Control barrier functions 612 outputs vehicle commands 614 that are either unchanged from the low-level commands 610 or modified to make the low-level commands 610 safe.

At block 1110 the vehicle commands 614 are output to a computing device 115 in a vehicle to determine commands to be communicated to controllers 112, 113, 114 to control vehicle powertrain, steering, and brakes to operate vehicle 110. Vehicle commands 614 are also output to action translator 616 for translation back into high-level commands. The translated high-level commands are compared to original high-level commands 606 output from DRL 604 and combined with vehicle data as discussed above in relation to FIG. 6 to form reward functions. The reward functions are input to DRL agent 604 to train the DRL agent 604 based on the output from control barrier functions 612 as discussed in relation to FIGS. 5 and 6. Following block 1110 process 1100 ends.

Computing devices such as those discussed herein generally each includes commands executable by one or more computing devices such as those identified above, and for carrying out blocks or steps of processes described above. For example, process blocks discussed above may be embodied as computer-executable commands.

Computer-executable commands may be compiled or interpreted from computer programs created using a variety of programming languages and/or technologies, including, without limitation, and either alone or in combination, Java™, C, C++, Python, Julia, SCALA, Visual Basic, Java Script, Perl, HTML, etc. In general, a processor (e.g., a microprocessor) receives commands, e.g., from a memory, a computer-readable medium, etc., and executes these commands, thereby performing one or more processes, including one or more of the processes described herein. Such commands and other data may be stored in files and transmitted using a variety of computer-readable media. A file in a computing device is generally a collection of data stored on a computer readable medium, such as a storage medium, a random access memory, etc.

A computer-readable medium (also referred to as a processor-readable medium) includes any non-transitory (e.g., tangible) medium that participates in providing data (e.g., instructions) that may be read by a computer (e.g., by a processor of a computer). Such a medium may take many forms, including, but not limited to, non-volatile media and volatile media. Instructions may be transmitted by one or more transmission media, including fiber optics, wires, wireless communication, including the internals that comprise a system bus coupled to a processor of a computer. Common forms of computer-readable media include, for example, RAM, a PROM, an EPROM, a FLASH-EEPROM, any other memory chip or cartridge, or any other medium from which a computer can read.

All terms used in the claims are intended to be given their plain and ordinary meanings as understood by those skilled in the art unless an explicit indication to the contrary in made herein. In particular, use of the singular articles such as “a,” “the,” “said,” etc. should be read to recite one or more of the indicated elements unless a claim recites an explicit limitation to the contrary.

The term “exemplary” is used herein in the sense of signifying an example, e.g., a reference to an “exemplary widget” should be read as simply referring to an example of a widget.

The adverb “approximately” modifying a value or result means that a shape, structure, measurement, value, determination, calculation, etc. may deviate from an exactly described geometry, distance, measurement, value, determination, calculation, etc., because of imperfections in materials, machining, manufacturing, sensor measurements, computations, processing time, communications time, etc.

In the drawings, the same reference numbers indicate the same elements. Further, some or all of these elements could be changed. With regard to the media, processes, systems, methods, etc. described herein, it should be understood that, although the steps or blocks of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating certain embodiments, and should in no way be construed so as to limit the claimed invention.

1. A computer, comprising:
a processor; and
a memory, the memory including instructions executable by the processor to:
determine a first action based on inputting sensor data to a deep reinforcement learning neural network;
transform the first action to one or more first commands;
determine one or more second commands by inputting the one or more first commands to control barrier functions;
transform the one or more second commands to a second action;
determine a reward function by comparing the second action to the first action; and
output the one or more second commands.

2. The computer of claim 1, the instructions including further instructions to operate a vehicle based on the one or more second commands.

3. The computer of claim 2, the instructions including further instructions to operate the vehicle by controlling vehicle powertrain, vehicle brakes, and vehicle steering.

4. The computer of claim 1, the instructions including further instructions to train the deep reinforcement learning neural network based on the reward function.

5. The computer of claim 1, wherein the first action includes one or more longitudinal actions including maintain speed, accelerate at a low rate, decelerate at a low rate, and decelerate at a medium rate.

6. The computer of claim 1, wherein the first action includes one or more of lateral actions including maintain lane, left lane change, and right lane change.

7. The computer of claim 1, wherein the control barrier functions include lateral control barrier functions and longitudinal control barrier functions.

8. The computer of claim 7, wherein the longitudinal control barrier functions are based on maintaining a distance between a vehicle and an in-lane following vehicle and an in-lane leading vehicle.

9. The computer of claim 7, wherein the lateral control barrier functions are based on lateral distances between a vehicle and other vehicles in adjacent lanes and steering effort based on avoiding the other vehicles in the adjacent lanes.

10. The computer of claim 1, wherein the deep reinforcement learning neural network approximates a Markov decision process.

11. A method, comprising:
determining a first action based on inputting sensor data to a deep reinforcement learning neural network;
transforming the first action to one or more first commands;
determining one or more second commands by inputting the one or more first commands to control barrier functions;
transforming the one or more second commands to a second action;
determining a reward function by comparing the second action to the first action; and
output the one or more second commands.

12. The method of claim 11, further comprising operating a vehicle based on the one or more second commands.

13. The method of claim 12, further comprising operating the vehicle by controlling vehicle powertrain, vehicle brakes, and vehicle steering.

14. The method of claim 11, further comprising training the deep reinforcement learning neural network based on the reward function.

15. The method of claim 11, wherein the first action includes one or more longitudinal actions including maintain speed, accelerate at a low rate, decelerate at a low rate, and decelerate at a medium rate.

16. The method of claim 11, wherein the first action includes one or more of lateral actions including maintain lane, left lane change, and right lane change.

17. The method of claim 11, wherein the control barrier functions include lateral control barrier functions and longitudinal control barrier functions.

18. The method of claim 17, wherein the longitudinal control barrier functions are based on maintaining a distance between a vehicle and an in-lane following vehicle and an in-lane leading vehicle.

19. The method of claim 17, wherein the lateral control barrier functions are based on lateral distances between a vehicle and other vehicles in adjacent lanes and steering effort based on avoiding the other vehicles in the adjacent lanes.

20. The method of claim 11, wherein the deep reinforcement learning neural network approximates a Markov decision process.
